(19) United States
(12) Patent Application Publication
(10) Pub. No.: US 2026/0214997 A1
(43) Pub. Date: Jul. 23, 2026

(54) BIDIRECTIONAL ASYMMETRIC VOLTAGE PROTECTION DEVICE AND PREPARATION METHOD THEREOF

(71) Applicant: WAYON SEMICONDUCTOR CO., LTD., Shanghai (CN)

(72) Inventors: Qianwan JIANG, Shanghai (CN); Kaihua CHEN, Shanghai (CN); Wei ZHANG, Shanghai (CN); Deyi ZHAO, Shanghai (CN); Yanguo GU, Shanghai (CN); Xiao ZHANG, Shanghai (CN); Jiahao LI, Shanghai (CN); Jiale WANG, Shanghai (CN)

(73) Assignee: WAYON SEMICONDUCTOR CO., LTD., Shanghai (CN)

(21) Appl. No.: 19/374,506

(22) Filed: Oct. 30, 2025

(30) Foreign Application Priority Data
Jan. 22, 2025 (CN) 2025100964185

(51) Int. Cl. H10D 89/60

(52) U.S. Cl. CPC H10D 89/711; H10D 89/611

(57) ABSTRACT

A bidirectional asymmetric voltage protection device, comprising: a first unidirectional conduction unit, an input end of which is connected with a first port; a second unidirectional conduction unit, an input end of which is connected with a second port; a third unidirectional conduction unit, an output end of which is connected with the first port; a fourth unidirectional conduction unit, an output end of which is connected with the second port; a first transistor unit, an input end of which is connected with an output end of the first unidirectional conduction unit; a second transistor unit, an input end of which is connected with an output end of the first transistor unit and an output end of the second unidirectional conduction unit respectively. Figure to be published: Fig. 1

### FIELD OF THE INVENTION

The present invention relates to the technical field of semiconductor protection devices, and in particular, to a bidirectional asymmetric voltage protection device and a preparation method thereof.

### DESCRIPTION OF THE RELATED ART

A Transient Voltage Suppressor (TVS) is a commonly used protection device, widely applied in interface circuits of various electronic devices, including but not limited to, mobile phones, tablet computers, televisions, and computer hosts. The input/output (I/O) port of the TVS device is typically connected with the I/O port of the circuit, and its ground terminal is connected with the ground line of the circuit, meaning the TVS device is connected in parallel with the protected chip. When the circuit I/O port is threatened by transient voltages such as electrostatic discharge (ESD) or surge voltages, the TVS device is triggered to conduct preferentially, allowing current to be discharged to ground through the TVS device. This clamps these high voltages to a relatively low level within an extremely short time, thereby ensuring that the subsequent integrated circuit (IC) is not damaged by overvoltage.

With the rapid development of microelectronic technology, integrated circuits continue to evolve toward lower voltage, lower power consumption, and higher-speed transmission. Accordingly, higher performance requirements are imposed on TVS protection devices, demanding lower parasitic capacitance and stronger protection capability. In certain specific application scenarios, special requirements are placed on bidirectional protection devices to prevent damage caused by incorrect connections. For example, in Type-C interfaces, due to the close proximity of the D+ and D- ports to the VBUS port, mis insertion may cause the D+ and D- ports to withstand voltages as high as 12V or more. Therefore, a TVS device with bidirectional protection functionality is required, where the breakdown voltage in one direction must be sufficiently high to withstand such high voltage impacts from mis insertion, while the other direction maintains a lower breakdown voltage to ensure signal integrity and effective protection of the subsequent circuit.

### SUMMARY OF THE INVENTION

To solve the above-mentioned technical issues, the invention provides a bidirectional asymmetric voltage protection device. On the other hand, the invention further provides a preparation method of the bidirectional asymmetric voltage protection device.

The technical issue solved by this invention could be implemented by the following technical solution.

A bidirectional asymmetric voltage protection device, wherein the device is formed in a semiconductor substrate and connected between a first port and a second port, comprising:

a first unidirectional conduction unit, an input end of which is connected with the first port;

a second unidirectional conduction unit, an input end of which is connected with the second port;

a third unidirectional conduction unit, an output end of which is connected with the first port;

a fourth unidirectional conduction unit, an output end of which is connected with the second port;

a first transistor unit, an input end of which is connected with an output end of the first unidirectional conduction unit;

a second transistor unit, an input end of which is connected with an output end of the first transistor unit and an output end of the second unidirectional conduction unit respectively, and an output end of the second transistor unit is connected with an input end of the third unidirectional conduction unit and an input end of the fourth unidirectional conduction unit respectively.

Preferably, the semiconductor substrate comprises;

a P-type first epitaxial layer formed on a surface of a P+ type substrate;

an N-type buried layer formed on a surface of the P-type first epitaxial layer;

an N-type second epitaxial layer formed on a surface of the N-type buried layer, wherein the device is formed in the N-type second epitaxial layer of the semiconductor substrate.

Preferably, the bidirectional asymmetric voltage protection device, further comprising:

a plurality of isolation trenches, the plurality of isolation trenches extending downward from a surface of the semiconductor substrate to isolate the first unidirectional conduction unit, the second unidirectional conduction unit, the third unidirectional conduction unit, the fourth unidirectional conduction unit, the first transistor unit, and the second transistor unit respectively.

Preferably, a control end of the first transistor unit is connected with the output end of the first transistor unit or is floatingly connected; and

a control end of the second transistor unit is connected with an output end thereof or is floatingly connected.

Preferably, the first unidirectional conduction unit comprises a first P+ region and a first N+ region, the first P+ region and the first N+ region being formed in the semiconductor substrate respectively;

the second unidirectional conduction unit comprises a second P+ region and a second N+ region, the second P+ region and the second N+ region being formed in the semiconductor substrate respectively;

the third unidirectional conduction unit comprises a first P-type well region, a third P+ region and a third N+ region, the first P-type well region being formed in the semiconductor substrate, the third P+ region and the third N+ region being formed in the first P-type well region respectively;

the fourth unidirectional conduction unit comprises a second P-type well region, a fourth P+ region and a fourth N+ region, the second P-type well region being formed in the semiconductor substrate, the fourth P+ region and the fourth N+ region being formed in the second P-type well region respectively.

Preferably, the first transistor unit comprises:

an N-type well region formed in the semiconductor substrate;

a penetration region extending downward from a surface of the semiconductor substrate to a bottom of the N-type well region;

a fifth N+ region formed in the penetration region;

a P-type base region formed in the N-type well region;

a sixth N+ region formed in the P-type base region.

Preferably, the first transistor unit further comprises:

a fifth P+ region formed in the P-type base region.

Preferably, the first transistor unit comprises:

an N-type well region formed in the semiconductor substrate;

a fifth N+ region formed in the N-type well region;

a P-type base region formed in the N-type well region;

a fifth P+ region and a sixth N+ region formed in the P-type base region respectively;

a polysilicon layer formed on a surface of a field oxide layer between the fifth N+ region and the P-type base region.

Preferably, the second transistor unit comprises:

a third P-type well region formed in the semiconductor substrate;

a seventh N+ region formed in the third P-type well region;

a fourth P-type well region formed in the third P-type well region;

an eighth N+ region formed in the fourth P-type well region.

Preferably, the second transistor unit further comprises:

a sixth P+ region formed in the third P-type well region.

The invention further provides a method for preparing a bidirectional asymmetric voltage protection device, comprising:

forming, in a semiconductor substrate, a first unidirectional conduction unit, a second unidirectional conduction unit, a third unidirectional conduction unit, a fourth unidirectional conduction unit, a first transistor unit, and a second transistor unit respectively;

wherein an input end of the first unidirectional conduction unit is connected with a first port, an output end of the first unidirectional conduction unit is connected with an input end of the first transistor unit, an output end of the first transistor unit is connected with an input end of the second transistor unit, an output end of the second transistor unit is connected with an input end of the third unidirectional conduction unit and an input end of the fourth unidirectional conduction unit respectively, an output end of the fourth unidirectional conduction unit is connected with a second port, an input end of the second unidirectional conduction unit is connected with the second port, an output end of the second unidirectional conduction unit is connected with the input end of the second transistor unit, and an output end of the third unidirectional conduction unit is connected with the first port.

The beneficial technical effects of the present invention are as follows.

The device of the present invention has bidirectional protection functionality, with different breakdown voltages in the two directions. The direction from the first port to the second port has a higher breakdown voltage, enabling it to withstand high-voltage impacts caused by mis insertion. In the direction from the second port to the first port, the absence of the first transistor unit results in a lower breakdown voltage, providing improved protection for signal transmission, more effective safeguarding of the subsequent circuit, and ensuring the integrity of high-speed signal data transmission. Simultaneously, leveraging the negative resistance characteristics of the transistor, both directions exhibit low on-resistance and high surge capability.

### BRIEF DESCRIPTION OF THE DRAWINGS

FIG. 1 is a schematic diagram of an equivalent circuit of a bidirectional asymmetric voltage protection device according to a preferred embodiment 1 of the present invention;

FIG. 2 is a schematic structural diagram of the bidirectional asymmetric voltage protection device according to the preferred embodiment 1 of the present invention;

FIGS. 3a-3j are schematic cross-sectional diagrams of each step in a preparation method according to the preferred embodiment 1 of the present invention;

FIG. 4 is a schematic structural diagram of the bidirectional asymmetric voltage protection device according to a preferred embodiment 2 of the present invention;

FIG. 5 is a schematic diagram of an equivalent circuit of the bidirectional asymmetric voltage protection device according to the preferred embodiment 2 of the present invention;

FIG. 6 is a schematic diagram of an equivalent circuit of the bidirectional asymmetric voltage protection device according to a preferred embodiment 3 of the present invention.

In the drawings: 100 - first unidirectional conduction unit; 200 - second unidirectional conduction unit; 300 - third unidirectional conduction unit; 400 - fourth unidirectional conduction unit; 500 - first transistor unit; 600 - second transistor unit; 10 - semiconductor substrate;

1 – substrate; 2 - first epitaxial layer; 3 - buried layer; 4 - second epitaxial layer; 5 - isolation trench; 61 - N-type well region; 62 - first P-type well region; 63 - second P-type well region; 64 - third P-type well region; 65 - fourth P-type well region; 7 - penetration region; 8 - field oxide layer; 9 - P-type base region;

101 - first P+ region; 102 - second P+ region; 103 - third P+ region; 104 - fourth P+ region; 105 - fifth P+ region; 106 - sixth P+ region; 111 - first N+ region; 112 - second N+ region; 113 - third N+ region; 114 - fourth N+ region; 115 - fifth N+ region; 116 - sixth N+ region; 117 - seventh N+ region; 118 - eighth N+ region; 12 - polysilicon layer; 13 - dielectric layer; 131 - contact hole; 141 – first metal layer; 142 – second metal layer; 143 – third metal layer; 144 – fourth metal layer; 145 – fifth metal layer; 146 – sixth metal layer; 147 – seventh metal layer; 148 – eighth metal layer.

### DETAILED DESCRIPTION

The technical solutions in the embodiments of the present invention will be clearly and completely described below in conjunction with the accompanying drawings in the embodiments of the present invention. It is apparent that the described embodiments are merely a part of the embodiments of the present invention, rather than all of them. All other embodiments obtained by a person of ordinary skill in the art based on the embodiments of the present invention without making creative efforts shall fall within the protection scope of the present invention.

It should be noted that, in the absence of conflict, the embodiments in the present invention and the features in the embodiments may be combined with each other.

The present invention will be further described below in conjunction with the accompanying drawings and specific embodiments, but such description shall not be construed as limiting the invention.

### Embodiment 1

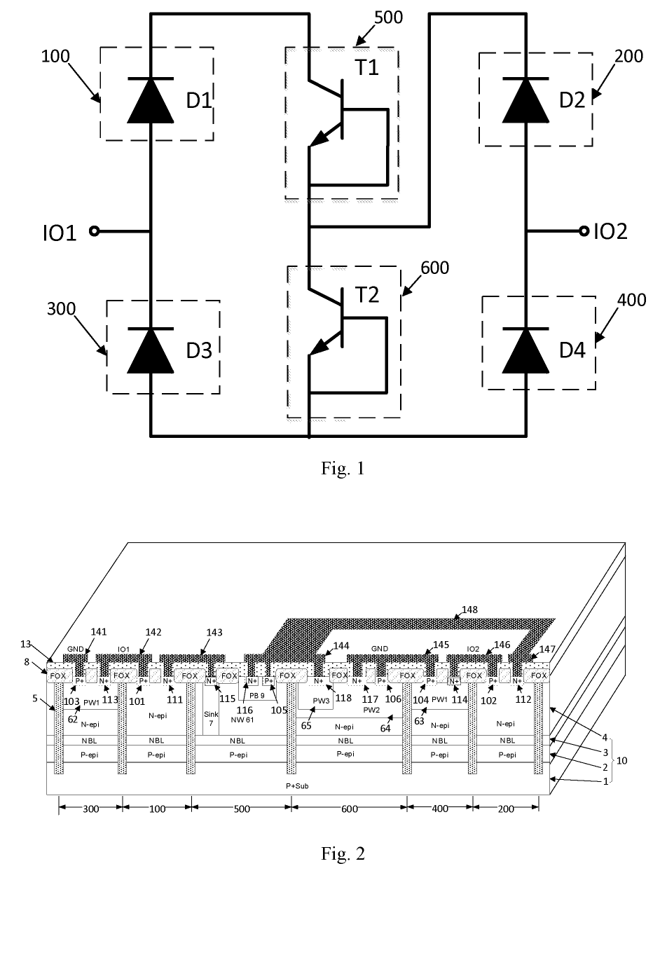

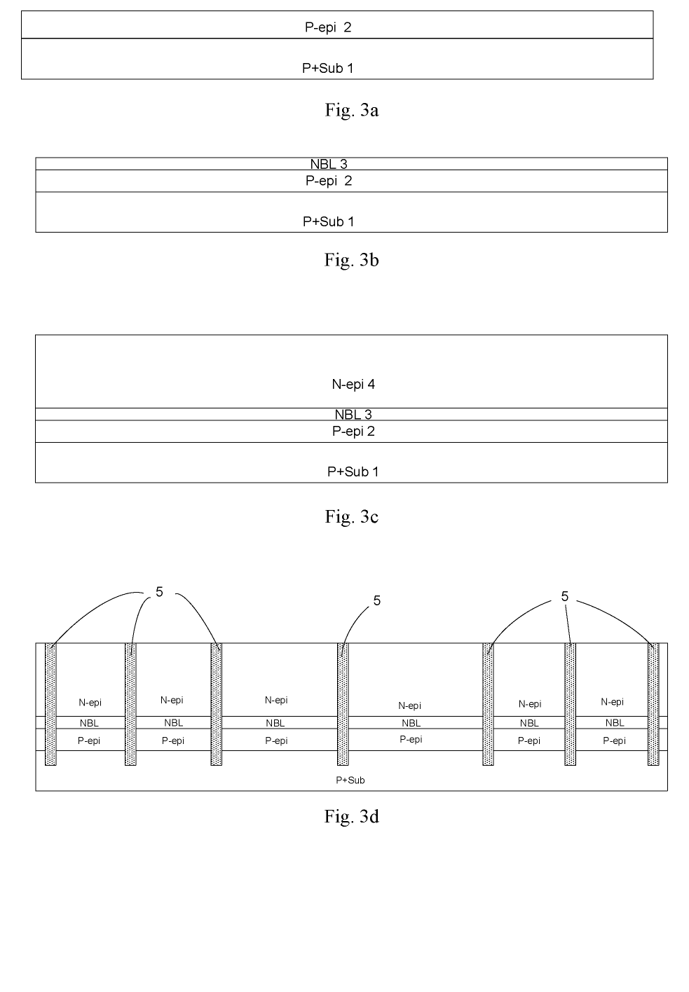

Referring to FIGS. 1 and 2, based on the issues in the prior art, there is provided a bidirectional asymmetric voltage protection device, wherein the device is formed in a semiconductor substrate 10 and connected between a first port IO1 and a second port IO2, comprising:

a first unidirectional conduction unit 100, an input end of the first unidirectional conduction unit 100 is connected with the first port;

a second unidirectional conduction unit 200, an input end of the second unidirectional conduction unit 200 is connected with the second port;

a third unidirectional conduction unit 300, an output end of the third unidirectional conduction unit 300 is connected with the first port;

a fourth unidirectional conduction unit 400, an output end of the fourth unidirectional conduction unit 400 is connected with the second port;

a first transistor unit 500, an input end of the first transistor unit 500 is connected with an output end of the first unidirectional conduction unit 100;

a second transistor unit 600, an input end of the second transistor unit 600 is connected with an output end of the first transistor unit 500 and an output end of the second unidirectional conduction unit 200 respectively, and an output end of the second transistor unit 600 is connected with an input end of the third unidirectional conduction unit 300 and an input end of the fourth unidirectional conduction unit 400 respectively.

Specifically, the device of the invention is composed of the first unidirectional conduction unit 100, the second unidirectional conduction unit 200, the third unidirectional conduction unit 300, the fourth unidirectional conduction unit 400, the fourth unidirectional conduction unit 400, the first transistor unit 500, and the second transistor unit 600. The first port IO1 is connected with the input end of the first transistor unit 500 through the first unidirectional conduction unit 100; the output end of the first transistor unit 500 is connected with the input end of the second transistor unit 600; the output end of the second transistor unit 600 is connected with the second port IO2 through the fourth unidirectional conduction unit 400; the second port IO2 is connected with the input end of the second transistor unit 600 through the second unidirectional conduction unit 200; the output end of the second transistor unit 600 is connected with the first port IO1 through the third unidirectional conduction unit 300.

The device has bidirectional protection functionality, with different breakdown voltages in the two directions, that is, the device has a first breakdown voltage in the IO1-IO2 direction and a second breakdown voltage in the IO2-IO1 direction, and the first breakdown voltage is greater than the second breakdown voltage. Wherein:

in the direction from the first port IO1 to the second port IO2: current flows from the first port IO1 sequentially through the first unidirectional conduction unit 100, the first transistor unit 500, the second transistor unit 600, and the fourth unidirectional conduction unit 400 to the second port IO2. The device has a first breakdown voltage in the IO1-IO2 direction, which is relatively high and capable of withstanding high-voltage impacts caused by port misinsertion;

in the direction from the second port IO2 to the first port IO1: current flows from the second port IO2 sequentially through the second unidirectional conduction unit 200, the second transistor unit 600, and the third unidirectional conduction unit 300 to the first port IO1. Since the first transistor unit 500 is not traversed, the device has a lower second breakdown voltage in the IO2-IO1 direction, enabling improved protection of signal transmission, more effective safeguarding of subsequent circuits, and ensuring the integrity of high-speed signal data transmission.

In this embodiment, the first unidirectional conduction unit 100, the second unidirectional conduction unit 200, the third unidirectional conduction unit 300, and the fourth unidirectional conduction unit 400 are all diodes. That is, the first unidirectional conduction unit 100 comprises a first diode D1, the second unidirectional conduction unit 200 comprises a second diode D2, the third unidirectional conduction unit 300 comprises a third diode D3, and the fourth unidirectional conduction unit 400 comprises a fourth diode D4.

The first to fourth diodes may be PN junction diodes, Schottky diodes, or other types of unidirectional conductive diodes.

In this embodiment, the first transistor unit 500 comprises a first transistor T1, and the second transistor unit 600 comprises a second transistor T2. The first transistor T1 and the second transistor T2 are bipolar transistors, field-effect transistors, or other types of transistors. Utilizing the negative resistance characteristics of the transistors, the device of the present invention exhibits low on-resistance and high surge capability in both directions.

The equivalent circuit of the device of the present invention is shown in FIG. 1. The anode of the first diode D1 is connected with the first port IO1, and the cathode of the first diode D1 is connected with the collector of the first transistor T1. The emitter of the first transistor T1 and the collector of the second transistor T2 are connected with the cathode of the second diode D2 respectively. The anode of the second diode D2 is connected with the second port IO2. The emitter of the second transistor T2 is connected with the cathode of the third diode D3 and the cathode of the fourth diode D4 respectively. The anode of the third diode D3 is connected with the first port IO1, and the anode of the fourth diode D4 is connected with the second port IO2.

Furthermore, the semiconductor substrate 10 comprises a substrate 1, a first epitaxial layer 2, a buried layer 3, and a second epitaxial layer 4; wherein the substrate 1 has a first conductivity type; the first epitaxial layer 2 is formed on a surface of the substrate 1, and the first epitaxial layer 2 has the same conductivity type as the substrate 1 but has a doping concentration lower than that of the substrate 1; the buried layer 3 is formed on a surface of the first epitaxial layer 2, and the buried layer 3 has a second conductivity type opposite to the first conductivity type; the second epitaxial layer 4 is formed on a surface of the buried layer 3, and the second epitaxial layer 4 has the same conductivity type as the buried layer 3 but has a doping concentration lower than that of the buried layer 3. The device of the present invention is formed in the second epitaxial layer 4 of the semiconductor substrate 10.

In this embodiment, the first conductivity type is P-type, and the second conductivity type is N-type. In the drawings, the corresponding doping concentration is indicated by “+” following the doping type “N” or “P.” For example, “N+” denotes a doping concentration higher than that of an N-type doped region. Doped regions having the same relative doping concentration do not necessarily have the same absolute doping concentration. For example, two different n-doped regions may have the same or different absolute doping concentrations.

As a preferred embodiment, the semiconductor substrate 10 comprises;

a P-type first epitaxial layer 2 formed on a surface of a P+ type substrate 1;

an N-type buried layer 3 formed on a surface of the P-type first epitaxial layer 2;

an N-type second epitaxial layer 4 formed on a surface of the N-type buried layer 3, wherein the device is formed in the N-type second epitaxial layer 4 of the semiconductor substrate 10.

In this embodiment, the P+ type substrate 1 is selected from a low-resistance material with a resistivity of less than 0.1 Ω·cm.

In this embodiment, the P-type first epitaxial layer 2 has a thickness of 5 μm to 15 μm and has a resistivity greater than 1 Ω·cm. Preferably, the P-type first epitaxial layer 2 has a resistivity of 10 Ω·cm to 20 Ω·cm. The use of a high-resistivity P-type first epitaxial layer 2 or a relatively thick P-type first epitaxial layer 2 in the present invention is beneficial for improving isolation voltage and ensuring normal operation of the device.

In this embodiment, the implanted elements of the N-type buried layer 3 are arsenic or antimony, with an implantation dose of 1E15/cm² to 1E16/cm² and an implantation energy of 80 to 200 KeV. After element implantation, a high-temperature drive-in process is performed. The high-temperature drive-in temperature ranges from 1100°C to 1200°C, with a duration of 60 to 120 minutes, thereby enabling the N-type buried layer to achieve a certain thickness.

Furthermore, before growing the N-type second epitaxial layer 4, the aforementioned silicon wafer (comprising the P+ type substrate 1, the P-type first epitaxial layer 2, and the N-type buried layer 3) must be cleaned to ensure the absence of impurity particles and native oxide layers on the silicon wafer surface. Subsequently, the N-type second epitaxial layer 4 is grown.

In this embodiment, the N-type second epitaxial layer 4 is selected with a high-resistance specification, having a resistivity greater than 10 Ω·cm and a thickness greater than 5 μm. The use of a high-resistivity epitaxial layer is beneficial for reducing the device capacitance, enabling the device of the present invention to be applied to high-speed signal transmission ports.

As a preferred embodiment, the device further comprises: a plurality of isolation trenches 5, the plurality of isolation trenches 5 extending downward from a surface of the semiconductor substrate 10 to isolate the first unidirectional conduction unit 100, the second unidirectional conduction unit 200, the third unidirectional conduction unit 300, the fourth unidirectional conduction unit 400, the first transistor unit 500, and the second transistor unit 600 respectively.

Specifically, by coating, exposing, and developing the surface of the semiconductor substrate 10, a deep trench etching region window is defined. Deep trenches are then etched by dry etching, and the deep trenches are filled with silicon dioxide or undoped polysilicon to form isolation trenches 5 (DTI).

Furthermore, after forming the isolation trenches 5, excess silicon dioxide or undoped polysilicon on the upper surface of the semiconductor substrate 10 is removed, retaining only the film material within the trenches.

Preferably, the depth of the isolation trenches 5 is greater than the sum of the thicknesses of the P-type first epitaxial layer 2 and the N-type second epitaxial layer 4. The width of the isolation trenches 5 is 0.8μm to 1.6μm.

As a preferred embodiment, a control end of the first transistor unit 500 is connected with the output end thereof; and

a control end of the second transistor unit 600 is connected with an output end thereof.

Specifically, both the first transistor unit 500 and the second transistor unit 600 are semiconductor devices with control ends. During normal operation of the device, the control ends are configured not to directly participate in the voltage protection process, or the control ends are fixedly biased to maintain the transistor units in a specific operating state.

As a preferred embodiment, the first unidirectional conduction unit 100 comprises a first P+ region 101 and a first N+ region 111, the first P+ region 101 and the first N+ region 111 being formed in the semiconductor substrate 10 respectively.

Specifically, in this embodiment, the first diode D1 is an ultra-low capacitance diode formed by the first P+ region 101, the N-type second epitaxial layer 4, and the first N+ region 111.

The first P+ region 101 serves as the anode of the first diode D1 and contacts the metal layer corresponding to the first port IO1.

As a preferred embodiment, the second unidirectional conduction unit 200 comprises a second P+ region 102 and a second N+ region 112, the second P+ region 102 and the second N+ region 112 being formed in the semiconductor substrate 10 respectively.

Specifically, in this embodiment, the second diode D2 is an ultra-low capacitance diode formed by the second P+ region 102, the N-type second epitaxial layer 4, and the second N+ region 112.

The second P+ region 102 serves as the anode of the second diode D2 and contacts the metal layer corresponding to the second port IO2.

As a preferred embodiment, the third unidirectional conduction unit 300 comprises a first P-type well region 62, a third P+ region 103 and a third N+ region 113, the first P-type well region 62 being formed in the semiconductor substrate 10, the third P+ region 103 and the third N+ region 113 being formed in the first P-type well region 62 respectively.

Specifically, in this embodiment, the third diode D3 is an ultra-low capacitance diode formed by the third P+ region 103, the first P-type well region 62, and the third N+ region 113.

The third N+ region 113 serves as the cathode of the third diode D3 and contacts the metal layer corresponding to the first port IO1.

As a preferred embodiment, the fourth unidirectional conduction unit 400 comprises a second P-type well region 63, a fourth P+ region 104 and a fourth N+ region 114, the second P-type well region 63 being formed in the semiconductor substrate 10, the fourth P+ region 104 and the fourth N+ region 114 being formed in the second P-type well region 63 respectively.

Specifically, in this embodiment, the fourth diode D4 is an ultra-low capacitance diode formed by the fourth P+ region 104, the second P-type well region 63, and the fourth N+ region 114.

The fourth N+ region 114 serves as the cathode of the fourth diode D4 and contacts the metal layer corresponding to the second port IO2.

Furthermore, the aforementioned first P-type well region 62 and second P-type well region 63 may be formed using the same PW1 photolithographic implantation process to simplify the preparation flow. Specifically, the PW1 implantation window is defined by PW1 photolithography, followed by PW1 ion implantation.

In this embodiment, the implanted element for both the first P-type well region 62 and the second P-type well region 63 is boron, with an implantation dose of 1E11 to 1E13/cm² and an implantation energy of 60 to 100 KeV.

As a preferred embodiment, the first transistor unit 500 comprises:

an N-type well region 61 formed in the semiconductor substrate 10;

a penetration region 7 extending downward from a surface of the semiconductor substrate 10 to a bottom of the N-type well region 61;

a fifth N+ region 115 formed in the penetration region 7;

a P-type base region 9 formed in the N-type well region 61;

a sixth N+ region 116 and a fifth P+ region 105, formed in the P-type base region 9 respectively.

Furthermore, in the step of forming the N-type well region 61, the NW implantation window is defined by NW photolithography, followed by NW ion implantation. Preferably, the implanted element for the N-type well region 61 is phosphorus, with an implantation dose of 1E12 to 5E13/cm² and an implantation energy of 60 to 150 KeV.

Furthermore, in the step of forming the penetration region 7 (Sink), the Sink implantation window is defined by Sink photolithography, followed by Sink ion implantation. Preferably, the implanted element for the penetration region 7 is phosphorus, with an implantation dose of 1E14 to 1E15/cm², using high-energy ion implantation at an energy of 500 keV to 1 MeV. More preferably, the penetration region 7 may be formed by multiple implantations at different energies to achieve an improved doping profile.

Furthermore, in the step of forming the P-type base region 9, the PB implantation window is defined by PB photolithography, followed by PB ion implantation, and subsequently entering a furnace tube for high-temperature drive-in.

Preferably, the implanted element for the P-type base region 9 is boron or boron difluoride, with an implantation dose of 5E13 to 1E15/cm² and an implantation energy of 40 to 120 KeV. The high-temperature drive-in is performed at a temperature above 900°C for 30 to 60 minutes.

In this embodiment, the first transistor T1 is a bipolar transistor formed by the fifth N+ region 115, the penetration region 7, the N-type well region 61, the sixth N+ region 116, and the fifth P+ region 105, and has a relatively high breakdown voltage.

Specifically, the penetration region 7 is a heavily doped N-type region. The space charge region (depletion region) between the P-type base region 9 and the N-type well region 61 extends toward the penetration region 7. When it extends to the Sink region, breakdown occurs.

Furthermore, depending on application requirements, the transistor breakdown voltage can be adjusted through process control to achieve the first breakdown voltage. The first breakdown voltage is preferably 10 V to 40 V.

As a preferred embodiment, the second transistor unit 600 comprises:

a third P-type well region 64 formed in the semiconductor substrate 10;

a seventh N+ region 117 and a sixth P+ region 106 formed in the third P-type well region 64 respectively;

a fourth P-type well region 65 formed in the third P-type well region 64;

an eighth N+ region 118 formed in the fourth P-type well region 65.

Furthermore, in the step of forming the third P-type well region 64, the PW2 implantation window is defined by PW2 photolithography, followed by PW2 ion implantation. Subsequently, it is placed into a furnace tube for high-temperature drive-in to allow NW, PW1, and PW2 to diffuse to a certain depth.

Preferably, the implanted element for the third P-type well region 64 is boron, with an implantation dose of 1E13 to 1E14/cm² and an implantation energy of 40 to 60 KeV. The high-temperature drive-in is performed at a temperature above 1100°C for 30 to 120 minutes.

Furthermore, in the step of forming the fourth P-type well region 65, the PW3 implantation window is defined by PW3 photolithography, followed by PW3 ion implantation. Subsequently, it is placed into a furnace tube for high-temperature drive-in to allow Sink and PW3 to diffuse to a certain depth.

Preferably, the implanted element for the fourth P-type well region 65 is boron, with an implantation dose of 1E14 to 1E15/cm² and an implantation energy of 50 to 100 KeV. The high-temperature drive-in is performed at a temperature above 1000°C for 30 to 120 minutes.

In this embodiment, the second transistor T2 is another bipolar transistor formed by the eighth N+ region 118, the fourth P-type well region 65, the third P-type well region 64, the seventh N+ region 117, and the sixth P+ region 106, and has a relatively high breakdown voltage.

Furthermore, depending on application requirements, the transistor breakdown voltage can be adjusted through process control to achieve the second breakdown voltage. The second breakdown voltage is preferably in the range of 3.3 V to 10 V.

Furthermore, the device of the present invention further comprises:

a field oxide layer 8 formed on a surface of the semiconductor substrate 10, alternately arranged with active regions of each unit (including the aforementioned first to eighth N+ regions and first to sixth P+ regions);

a dielectric layer 13 formed on the surface of the semiconductor substrate 10, wherein a plurality of contact holes 131 are formed in the dielectric layer 13;

a metal layer formed in the contact holes 131.

Specifically, in the step of forming the field oxide layer 8, active regions are prepared on the surface of the semiconductor substrate 10 using a local oxidation technology. The process is as follows: first, a thin oxide layer is grown, followed by the deposition of a silicon nitride layer, partial silicon nitride is removed by photolithography and dry etching, then the field oxide layer 8 (FOX) is grown, subsequently, the remaining silicon nitride is removed by wet etching.

Preferably, the field oxide layer 8 has a thickness of 4000–8000 Å and is grown in a high-temperature furnace tube at a temperature of 950–1050°C, with oxygen and hydrogen introduced as gases.

The silicon nitride layer is deposited to a thickness of 1000–2000 Å. The wet etching process for removing the silicon nitride uses hot phosphoric acid at 80°C, and the silicon nitride can be completely removed after 45–60 minutes of etching.

Furthermore, the aforementioned first to eighth N+ regions may be prepared using the same N+ ion implantation process. Similarly, the aforementioned first to sixth P+ regions may also be prepared using the same P+ ion implantation process. Specifically, the N+ implantation window is first defined by N+ photolithography, followed by N+ ion implantation; then the P+ implantation window is defined by P+ photolithography, followed by P+ ion implantation; subsequently, a rapid thermal annealing process is performed to repair implantation damage and activate impurity ions.

Preferably, the implanted element for the first to eighth N+ regions is phosphorus, with an implantation dose of 1E15 to 1E16/cm² and an implantation energy of 40 to 120 KeV. The implanted element for the first to sixth P+ regions is boron or boron difluoride, with an implantation dose of 1E15 to 1E16/cm² and an implantation energy of 30 to 100 KeV. The rapid thermal annealing process is performed at a temperature above 1000°C for 20 to 40 seconds.

Furthermore, the contact holes 131 comprise a plurality of holes, the plurality of holes 131 corresponding to windows for the first to eighth N+ regions and the first to sixth P+ regions respectively.

Furthermore, in this embodiment, the metal layers sequentially comprise, from left to right, a first metal layer 141, a second metal layer 142, a third metal layer 143, a fourth metal layer 144, a fifth metal layer 145, a sixth metal layer 146, a seventh metal layer 147, and an eighth metal layer 148.

The first metal layer 141 serves as a grounding metal and contacts the third P+ region 103 to achieve an anode grounding connection for the third diode D3.

The second metal layer 142 serves as the contact metal corresponding to the first port IO1, contacting both the third N+ region 113 and the first P+ region 101, thereby enabling the cathode of the third diode D3 and the anode of the first diode D1 to be simultaneously connected with the first port IO1.

The third metal layer 143 contacts both the first N+ region 111 and the fifth N+ region 115 respectively, thereby connecting the cathode of the first diode D1 to the collector of the first transistor T1.

The fourth metal layer 144 contacts the sixth N+ region 116, the fifth P+ region 105, and the eighth N+ region 118, thereby connecting both the base and emitter of the first transistor T1 to the collector of the second transistor T2.

The fifth metal layer 145 serves as a grounding metal, contacting the seventh N+ region 117, the sixth P+ region 106, and the fourth P+ region 104, thereby achieving grounding connections for the base and emitter of the second transistor T2 and the anode of the fourth diode D4.

The sixth metal layer 146 serves as the contact metal corresponding to the second port IO2, contacting both the fourth N+ region 114 and the second P+ region 102, thereby enabling the anode of the second diode D2 and the cathode of the fourth diode D4 to be simultaneously connected to the second port IO2.

The seventh metal layer 147 contacts the second N+ region 112, and the eighth metal layer 148 adopts a "C"-shaped design to enable the seventh metal layer 147 to contact the aforementioned fourth metal layer 144, thereby connecting the cathode of the second diode D2 to the collector of the second transistor T2.

The invention further provides a method for preparing a bidirectional asymmetric voltage protection device, comprising:

forming, in a semiconductor substrate 10, a first unidirectional conduction unit 100, a second unidirectional conduction unit 200, a third unidirectional conduction unit 300, a fourth unidirectional conduction unit 400, a first transistor unit 500, and a second transistor unit 600 respectively;

wherein an input end of the first unidirectional conduction unit 100 is connected with a first port IO1, an output end of the first unidirectional conduction unit 100 is connected with an input end of the first transistor unit 500, an output end of the first transistor unit 500 is connected with an input end of the second transistor unit 600, an output end of the second transistor unit 600 is connected with an input end of the third unidirectional conduction unit 300 and an input end of the fourth unidirectional conduction unit 400 respectively, an output end of the fourth unidirectional conduction unit 400 is connected with a second port IO2, an input end of the second unidirectional conduction unit 200 is connected with the second port IO2, an output end of the second unidirectional conduction unit 200 is connected with the input end of the second transistor unit 600, and an output end of the third unidirectional conduction unit 300 is connected with the first port IO1.

Specifically, the bidirectional asymmetric voltage protection device using the preparation method of the present invention exhibits characteristics of flexible application. The preparation method of the present invention is described in detail below, comprising the steps of:

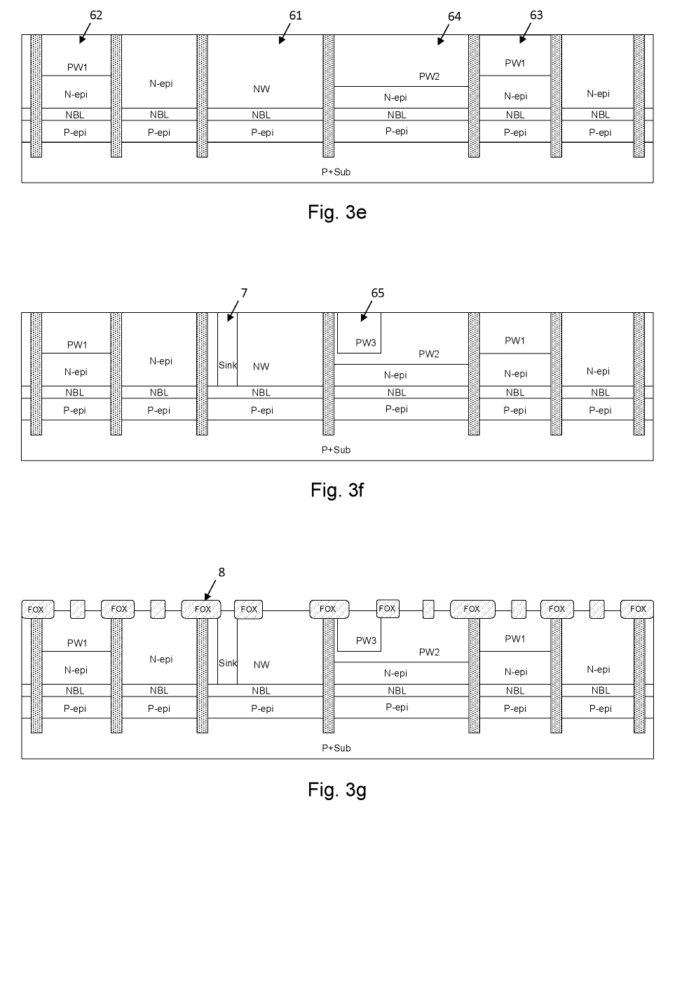

Step 1: as shown in FIG. 3a, first, a P-type first epitaxial layer 2 (P-epi) is grown on a P+ type substrate 1 by an epitaxial process.

Preferably, the P+ type substrate is selected from a low-resistance material with a resistivity of less than 0.1 Ω·cm. The P-type first epitaxial layer 2 has a thickness of 5–15 μm and has a resistivity greater than 1 Ω·cm; in this embodiment, it is 10–20 Ω·cm. The use of a high-resistivity P-type epitaxial layer or a relatively high thick P-type epitaxial layer is beneficial for improving isolation voltage and ensuring normal operation of the device.

Step 2: as shown in FIG. 3b, N-type ion implantation is performed on the aforementioned surface, followed by high-temperature drive-in to form an N-type buried layer 3 (NBL).

Preferably, the implanted elements for the N-type buried layer 3 are arsenic or antimony, with an implantation dose of 1E15 to 1E16/cm² and an implantation energy of 80 to 200 KeV. In the high-temperature drive-in process, the temperature ranges from 1100°C to 1200°C, and the duration is 60 to 120 minutes, enabling the N-type buried layer 3 to achieve a certain thickness.

Step 3: as shown in FIG. 3c, an N-type second epitaxial layer 4 (N-epi) is grown on the aforementioned surface by an epitaxial process.

Preferably, before epitaxial growth, the silicon wafer must be cleaned to ensure the absence of impurity particles and native oxide layers on the surface, after which epitaxial growth is performed. The N-type second epitaxial layer 4 is selected with a high-resistance specification, having a resistivity of at least greater than 10 Ω·cm and a thickness greater than 5μm. The use of a high-resistivity epitaxial layer is beneficial for reducing device capacitance, enabling the device of the present invention to be applied to high-speed signal transmission ports.

Step 4: as shown in FIG. 3d, coating, exposure, and development are performed on the aforementioned surface to define a deep trench etching region window. Deep trenches are then etched by dry etching and filled with silicon dioxide or undoped polysilicon to form isolation trenches 5 (DTI). Excess silicon dioxide or undoped polysilicon on the front side is subsequently removed, retaining only the film material within the trenches.

Preferably, the depth of the isolation trenches 5 is greater than the sum of the thicknesses of the P-type first epitaxial layer 2 and the N-type second epitaxial layer 4. The width of the isolation trenches 5 is 0.8–1.6 μm.

Step 5: as shown in FIG. 3e, an NW implantation window is defined by NW photolithography, followed by NW ion implantation to form an N-type well region 61; a PW1 implantation window is then defined by PW1 photolithography, followed by PW1 ion implantation to form a first P-type well region 62 and a second P-type well region 63; a PW2 implantation window is then defined by PW2 photolithography, followed by PW2 ion implantation to form a third P-type well region 64. Subsequently, it is placed into a furnace tube for high-temperature drive-in to allow the N-type well region 61, the first P-type well region 62, the second P-type well region 63, and the third P-type well region 64 to diffuse to a certain depth.

Preferably, the implanted element for the N-type well region 61 is phosphorus, with an implantation dose of 1E12 to 5E13/cm² and an implantation energy of 60 to 150 KeV. The first P-type well region 62 and the second P-type well region 63 are formed using the same PW1 process, with boron as the implanted element for both, an implantation dose of 1E11 to 1E13/cm², and an implantation energy of 60 to 100 KeV. The PW2 implantation uses boron as the element, with an implantation dose of 1E13 to 1E14/cm² and an implantation energy of 40 to 60 KeV. The high-temperature drive-in is performed at a temperature above 1100°C for 30 to 120 minutes.

Step 6: as shown in FIG. 3f, a Sink implantation window is defined by Sink photolithography, followed by Sink ion implantation to form a penetration region 7 in the N-type well region 61; a PW3 implantation window is then defined by PW3 photolithography, followed by PW3 ion implantation to form a fourth P-type well region 65. Subsequently, it is placed into a furnace tube for high-temperature drive-in to allow the penetration region 7 and the fourth P-type well region 65 to diffuse to a certain depth.

Preferably, the penetration region 7 is located within the N-type well region 61, with a depth equal to that of the N-type well region 61 and a width smaller than that of the N-type well region 61. The implanted element for the penetration region 7 is phosphorus, with an implantation dose of 1E14 to 1E15/cm², using high-energy ion implantation at an energy of 500 keV to 1 MeV. More preferably, the Sink region may be formed by multiple implantations at different energies to achieve an improved doping profile. The fourth P-type well region 65 is located within the second P-type well region 63, with boron as the implanted element, an implantation dose of 1E14 to 1E15/cm², and an implantation energy of 50 to 100 KeV. The high-temperature drive-in is performed at a temperature above 1000°C for 30 to 120 minutes.

Step 7: as shown in FIG. 3g, active regions are prepared on the aforementioned surface using a local oxidation technology: first, a thin oxide layer is grown, followed by the deposition of a silicon nitride layer; partial silicon nitride is removed by photolithography and dry etching; then, a field oxide layer 8 (FOX) is grown; subsequently, the remaining silicon nitride is removed by wet etching.

Preferably, the field oxide layer 8 has a thickness of 4000–8000 Å and is grown in a high-temperature furnace tube at a temperature of 950–1050 °C, with oxygen and hydrogen introduced as gases. The silicon nitride is deposited to a thickness of 1000–2000 Å. The wet etching process for removing the silicon nitride uses hot phosphoric acid at 80°C, and the silicon nitride can be completely removed after 45–60 minutes of etching.

Step 8: as shown in FIG. 3h, a PB implantation window is defined by PB photolithography, followed by PB ion implantation to form a P-type base region 9 (PB), which has a P-type doping and serves as the base region in an NPN transistor. Subsequently, it is placed into a furnace tube for high-temperature drive-in.

Preferably, the implanted element for the P-type base region 9 is boron or boron difluoride, with an implantation dose of 5E13 to 1E15/cm² and an implantation energy of 40 to 120 KeV. The high-temperature drive-in is performed at a temperature above 900°C for 30 to 60 minutes.

Step 9: as shown in FIG. 3i, an N+ implantation window is defined by N+ photolithography, followed by N+ ion implantation to form first to eighth N+ regions; a P+ implantation window is then defined by P+ photolithography, followed by P+ ion implantation to form first to sixth P+ regions. Subsequently, a rapid thermal annealing process is performed to repair implantation damage and activate impurity ions.

Preferably, the implanted element for the first to eighth N+ regions is phosphorus, with an implantation dose of 1E15 to 1E16/cm² and an implantation energy of 40 to 120 KeV. The implanted element for the first to sixth P+ regions is boron or boron difluoride, with an implantation dose of 1E15 to 1E16/cm² and an implantation energy of 30 to 100 KeV. The rapid thermal annealing process is performed at a temperature above 1000°C for 20 to 40 seconds.

Step 10: as shown in FIG. 3j, a dielectric layer 13 is deposited on the aforementioned surface, followed by photolithography and etching to form contact holes 131.

Preferably, the dielectric layer 13 may be an oxide layer, borophosphosilicate glass, or a combination of multiple insulating layers.

Step 11: Metal deposition is performed on the aforementioned surface, followed by photolithography and metal etching to form metal interconnects, with the connection configuration as shown in FIG. 2.

FIG. 1 shows an equivalent circuit diagram of the device according to Embodiment 1 of the present invention, wherein the first diode D1 and the second diode D2 are ultra-low capacitance diodes formed by P+/N-epi/N+ structures, and the third diode D3 and the fourth diode D4 are another type of ultra-low capacitance diodes formed by P+/PW1/N+ structures. The anode of the first diode D1 and the cathode of the third diode D3 are connected to the first port IO1, and the anode of the second diode D2 and the cathode of the fourth diode D4 are connected to the second port IO2.

The first transistor T1 is a bipolar transistor formed by an N+/Sink/NW/PB/N+/P+ structure, which has a relatively high breakdown voltage. Depending on application requirements, the voltage can be adjusted through process control to a range of 10 V to 40 V. The second transistor T2 is another bipolar transistor formed by an N+/PW3/PW2/N+/P+ structure, which has a relatively low breakdown voltage, controllable within the range of 3.3 V to 10 V. The collector of the first transistor T1 is connected to the cathode of the first diode D1; the base and emitter of the first transistor T1 are shorted together and simultaneously connected to the cathode of the second diode D2 and the collector of the second transistor T2; the base and emitter of the second transistor T2 are shorted together and simultaneously connected to the anodes of the third diode D3 and the fourth diode D4.

The present invention exhibits different breakdown voltages in the two directions. In the IO1-IO2 direction: after conduction, current flows from the IO1 port sequentially through the first diode D1, the first transistor T1, the second transistor T2, and the fourth diode D4 to the IO2 port, exhibiting a higher breakdown voltage. In the IO2-IO1 direction: after conduction, current flows from the IO2 port sequentially through D2, the second transistor T2, and the third diode D3 to the IO1 port; since the first transistor T1 is not traversed, this direction exhibits a lower breakdown voltage.

The device of the present invention, by utilizing the negative resistance characteristics of bipolar transistors in both the first transistor T1 and the second transistor T2, exhibits low on-resistance and higher surge capability in both directions during protection.

The device of the present invention, since the first diode D1, the second diode D2, the third diode D3, and the fourth diode D4 are ultra-low capacitance diodes, exhibits lower parasitic capacitance after being connected in series, thereby ensuring the integrity of high-speed signal data transmission.

### Embodiment 2

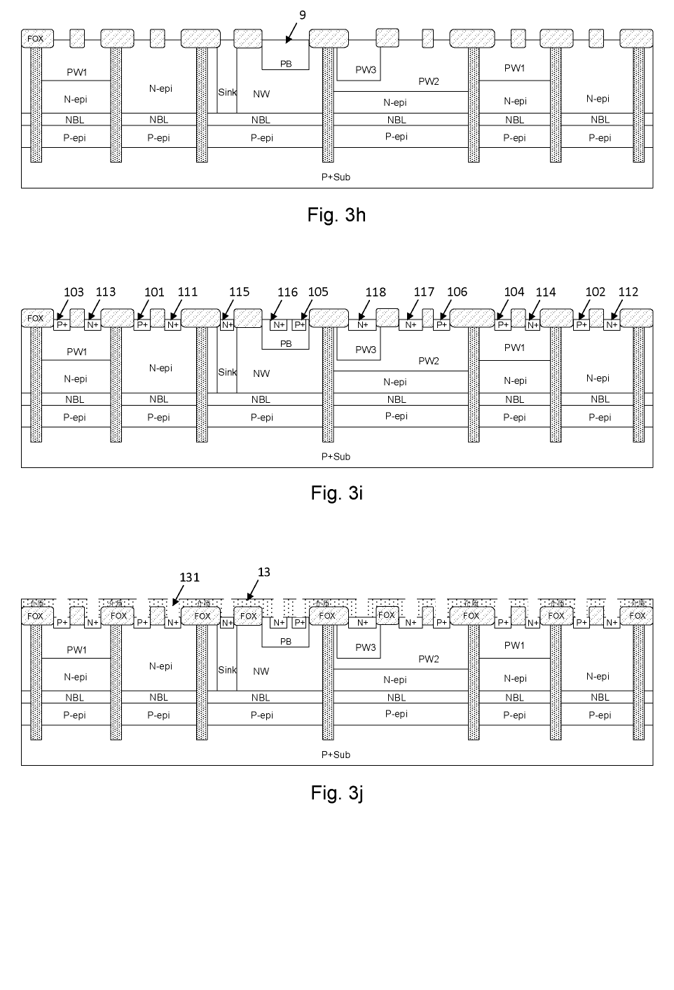

Embodiment 2 of the present invention provides a bidirectional asymmetric voltage protection device. As shown in FIG. 4, the difference from Embodiment 1 lies in the removal of the fifth P+ region 105 and the sixth P+ region 106 to alter the connection configuration of the first transistor T1 and the second transistor T2, without extracting the respective bases of the two transistors, while the functionality of the device remains unchanged.

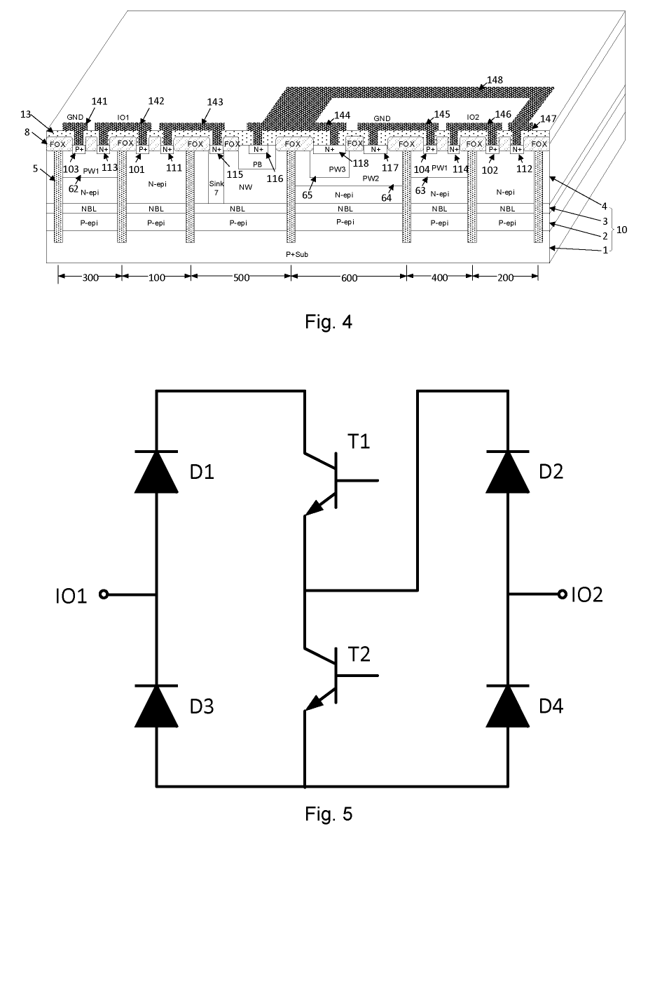

As a preferred embodiment, as shown in FIG. 5, a control end of the first transistor unit 500 is floatingly connected; and

a control end of the second transistor unit 600 is floatingly connected.

Specifically, in this embodiment, the control ends of both the first transistor unit 500 and the second transistor unit 600 are configured as floating connections, meaning the bases of the first transistor T1 and the second transistor T2 are in a floating state without electrical connection to the surrounding components.

### Embodiment 3

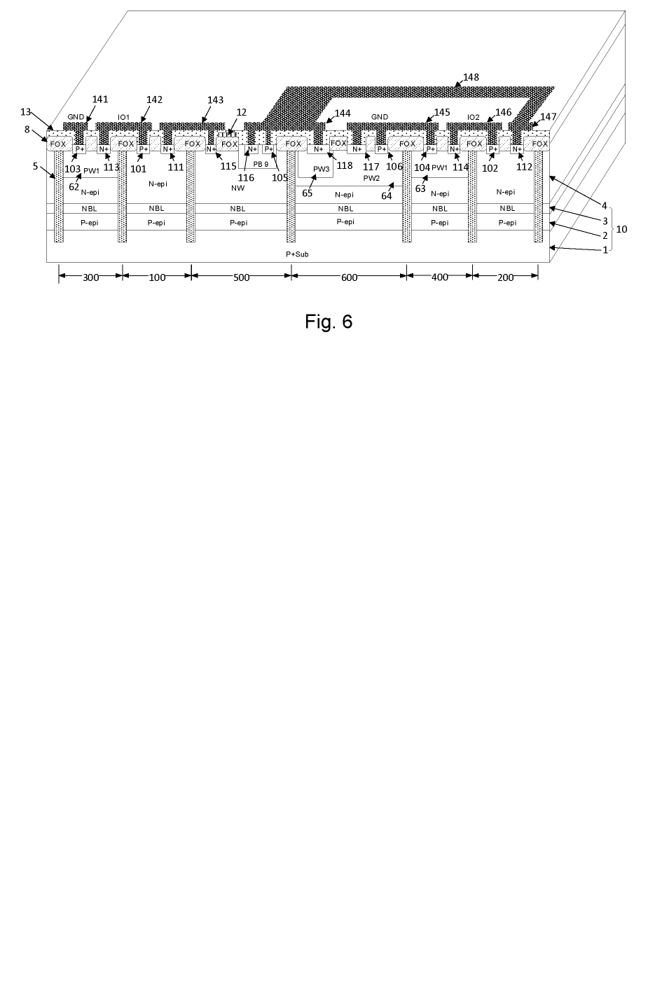

Embodiment 3 of the present invention provides a bidirectional asymmetric voltage protection device. As shown in FIG. 6, the difference from Embodiment 1 lies in the removal of the penetration region 7 (Sink) and the addition of a polysilicon layer 12 as a field plate on the field oxide layer 8 (FOX) on the left side of the P-type base region 9 (PB), so as to further enhance the breakdown voltage of the first transistor T1.

As a preferred embodiment, the first transistor unit 500 comprises:

an N-type well region 61 formed in the semiconductor substrate 10;

a fifth N+ region 115 formed in the N-type well region 61;

a P-type base region 9 formed in the N-type well region 61;

a sixth N+ region 116 and a fifth P+ region 105 formed in the P-type base region 9 respectively;

a polysilicon layer 12 formed on a surface of a field oxide layer 8 between the fifth N+ region 115 and the P-type base region 9.

Specifically, in Embodiment 1 and Embodiment 2 described above, due to the presence of the penetration region 7, the space charge region (depletion region) between the P-type base region 9 and the N-type well region 61 extends toward the penetration region 7. When it extends to the Sink region, breakdown occurs.

In Embodiment 3 of the present invention, after the penetration region 7 is removed, the space charge region between the P-type base region 9 and the N-type well region 61 is no longer constrained by the Sink region but continues to extend toward the N+ region, resulting in a wider space charge region in the device. Therefore, the device of the present invention exhibits a higher breakdown voltage.

A field plate can alter the distribution of electric field lines. In this embodiment, by adding a polysilicon layer 12 as a field plate on the field oxide layer 8 on the left side of the P-type base region 9, the breakdown point is shifted from the silicon surface to the bulk of the device. Since breakdown in the silicon bulk generally has a higher energy threshold than surface breakdown, the device of the present invention achieves a higher breakdown voltage, thereby improving its voltage withstand capability.

The advantages or beneficial effects of adopting the above technical solution are as follows: the present invention exhibits different breakdown voltages in the two directions. The IO1-IO2 direction has a higher breakdown voltage, and by utilizing the negative resistance characteristics of the transistor, both directions achieve low on-resistance and higher surge capability. The IO2-IO1 direction, as it does not pass through the first transistor unit, has a lower breakdown voltage, providing improved protection for signal transmission, more effective safeguarding of subsequent circuits, and ensuring the integrity of high-speed signal data transmission.

The foregoing describes only preferred embodiments of the invention, which therefore do not limit its embodiments or scope of protection. Those skilled in the art should recognize that all solutions obtained through equivalent substitutions or obvious modifications based on the specification and drawings of this invention shall fall within its protective scope.

1. A bidirectional asymmetric voltage protection device, wherein the device is formed in a semiconductor substrate and connected between a first port and a second port, comprising:
a. a first unidirectional conduction unit, an input end of which is connected with the first port;
b. a second unidirectional conduction unit, an input end of which is connected with the second port;
c. a third unidirectional conduction unit, an output end of which is connected with the first port;
d. a fourth unidirectional conduction unit, an output end of which is connected with the second port;
e. a first transistor unit, an input end of which is connected with an output end of the first unidirectional conduction unit;
f. a second transistor unit, an input end of which is connected with an output end of the first transistor unit and an output end of the second unidirectional conduction unit respectively, and an output end of the second transistor unit is connected with an input end of the third unidirectional conduction unit and an input end of the fourth unidirectional conduction unit respectively.

2. The bidirectional asymmetric voltage protection device of claim 1, wherein the semiconductor substrate comprises;
a. a P-type first epitaxial layer formed on a surface of a P+ type substrate;
b. an N-type buried layer formed on a surface of the P-type first epitaxial layer;
c. an N-type second epitaxial layer formed on a surface of the N-type buried layer, wherein the device is formed in the N-type second epitaxial layer of the semiconductor substrate.

3. The bidirectional asymmetric voltage protection device of claim 1, further comprising:
a. a plurality of isolation trenches, the plurality of isolation trenches extending downward from a surface of the semiconductor substrate to isolate the first unidirectional conduction unit, the second unidirectional conduction unit, the third unidirectional conduction unit, the fourth unidirectional conduction unit, the first transistor unit, and the second transistor unit respectively.

4. The bidirectional asymmetric voltage protection device of claim 1, wherein a control end of the first transistor unit is connected with the output end of the first transistor unit or is floatingly connected; and
a. a control end of the second transistor unit is connected with an output end thereof or is floatingly connected.

5. The bidirectional asymmetric voltage protection device of claim 1, wherein the first unidirectional conduction unit comprises a first P+ region and a first N+ region, the first P+ region and the first N+ region being formed in the semiconductor substrate respectively;
a. the second unidirectional conduction unit comprises a second P+ region and a second N+ region, the second P+ region and the second N+ region being formed in the semiconductor substrate respectively;
b. the third unidirectional conduction unit comprises a first P-type well region, a third P+ region and a third N+ region, the first P-type well region being formed in the semiconductor substrate, the third P+ region and the third N+ region being formed in the first P-type well region respectively;
c. the fourth unidirectional conduction unit comprises a second P-type well region, a fourth P+ region and a fourth N+ region, the second P-type well region being formed in the semiconductor substrate, the fourth P+ region and the fourth N+ region being formed in the second P-type well region respectively.

6. The bidirectional asymmetric voltage protection device of claim 1, wherein the first transistor unit comprises:
a. an N-type well region formed in the semiconductor substrate;
b. a penetration region extending downward from a surface of the semiconductor substrate to a bottom of the N-type well region;
c. a first N+ region formed in the penetration region;
d. a P-type base region formed in the N-type well region;
e. a sixth N+ region formed in the P-type base region.

7. The bidirectional asymmetric voltage protection device of claim 6, wherein the first transistor unit further comprises:
a. a fifth P+ region formed in the P-type base region.

8. The bidirectional asymmetric voltage protection device of claim 1, wherein the first transistor unit comprises:
a. an N-type well region formed in the semiconductor substrate;
b. a fifth N+ region formed in the N-type well region;
c. a P-type base region formed in the N-type well region;
d. a fifth P+ region and a sixth N+ region formed in the P-type base region respectively;
e. a polysilicon layer formed on a surface of a field oxide layer between the fifth N+ region and the P-type base region.

9. The bidirectional asymmetric voltage protection device of claim 1, wherein the second transistor unit comprises:
a. a third P-type well region formed in the semiconductor substrate;
b. a seventh N+ region and a sixth P+ region formed in the third P-type well region respectively;
c. a fourth P-type well region formed in the third P-type well region;
d. an eighth N+ region formed in the fourth P-type well region.

10. A method for preparing a bidirectional asymmetric voltage protection device, wherein the method is used for preparing the bidirectional asymmetric voltage protection device according to claim 1, comprising:
a. forming, in a semiconductor substrate, a first unidirectional conduction unit, a second unidirectional conduction unit, a third unidirectional conduction unit, a fourth unidirectional conduction unit, a first transistor unit, and a second transistor unit respectively;
b. wherein an input end of the first unidirectional conduction unit is connected with a first port, an output end of the first unidirectional conduction unit is connected with an input end of the first transistor unit, an output end of the first transistor unit is connected with an input end of the second transistor unit, an output end of the second transistor unit is connected with an input end of the third unidirectional conduction unit and an input end of the fourth unidirectional conduction unit respectively, an output end of the fourth unidirectional conduction unit is connected with a second port, an input end of the second unidirectional conduction unit is connected with the second port, an output end of the second unidirectional conduction unit is connected with the input end of the second transistor unit, and an output end of the third unidirectional conduction unit is connected with the first port.
